(19) United States
(12) Patent Application Publication
(10) Pub. No.: US 2026/0305134 A1
(43) Pub. Date: Oct. 1, 2026

(54) DISPLAY PANEL AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Tianci CHEN, Beijing (CN); Wei WANG, Beijing (CN); Siyu WANG, Beijing (CN); Yu WANG, Beijing (CN); Jianghua LIU, Beijing (CN); Chang LUO, Beijing (CN)

(21) Appl. No.: 19/477,871

(22) PCT Filed: Mar. 13, 2024
(86) PCT No.: PCT/CN2024/081524

§ 371 Date: Oct. 23, 2025

(30) Foreign Application Priority Data
Apr. 28, 2023 (CN) 202310487651.7

(51) Int. Cl. H10K 59/80; H10K 59/40

(52) U.S. Cl. CPC H10K 59/873; H10K 59/40

(57) ABSTRACT

A display panel includes a first organic layer, a first touch wire and a second touch wire, and the first touch wire and the second touch wire each include first section extending in a first direction. The first section of the first touch wire and the first section of the second touch wire each include a first sub-section and a second sub-section which are connected to each other, wherein the orthographic projection of the first sub-section on a base substrate does not overlap the orthographic projection of the first organic layer on the base substrate, and the orthographic projection of the second sub-section on the base substrate is located in the orthographic projection of a second area of the first organic layer on the base substrate. The first organic layer further includes a protruding block unit.

### CROSS-REFERENCE

This disclosure is a National Stage of International Application No. PCT/CN2024/081524, filed on Mar. 13, 2024, which claims priority to Chinese Patent Application No. 202310487651.7, filed on Apr. 28, 2023, entitled “Display Panel and Display Device”, the entire contents of which are incorporated herein by reference.

### TECHNICAL FIELD

This disclosure relates to the field of display technology, and more particularly to a display panel and a display device.

### BACKGROUND

In ultra-narrow bezel designs for display panels, some touch traces located at the bottom bezel of the display panel are positioned outside the barrier dam (used to block water and oxygen) of the display panel. Different locations of these touch traces have different distances from the base substrate of the display panel, and have a height difference, making them prone to short circuits during the manufacturing process.

The above information disclosed in this background section is intended only to enhance understanding of the background of this disclosure and may include information that does not constitute prior art known to persons of ordinary skill in the art.

### SUMMARY

This disclosure aims to provide a display panel and display device, to facilitate improving the quality of the display panel.

According to a first aspect of the present disclosure, a display panel is provided, including:
a base substrate, including a display area and a peripheral area located outside the display area, wherein the peripheral area includes a first peripheral area and a second peripheral area located at a side of the first peripheral area away from the display area;
a first organic layer, disposed on a side of the base substrate, wherein the first organic layer includes a second region, the second region is located in the second peripheral area;
a barrier dam, disposed on a side of the base substrate, wherein the barrier dam is located in the first peripheral area;
a touch layer, disposed on a side of the first organic layer away from the base substrate, wherein the touch layer includes a first touch trace and a second touch trace, each of the first touch trace and the second touch trace includes a first segment extending in a first direction, each of the first segments of the first touch trace and the second touch trace is located in the second peripheral area;
wherein each of the first segments of the first touch trace and the second touch trace includes a first sub-segment and a second sub-segment connected to each other, the first sub-segment and the second sub-segment of the first touch trace are at different distances from the base substrate, and the first sub-segment and the second sub-segment of the second touch trace are at different distances from the base substrate;
orthographic projections of the first sub-segments of the first touch trace and the second touch trace on the base substrate do not overlap with an orthographic projection of the first organic layer on the base substrate;
orthographic projections of the second sub-segments of the first touch trace and the second touch trace on the base substrate are located within an orthographic projection of the second region of the first organic layer on the base substrate;
the first organic layer further includes a bump unit, an orthographic projection of the bump unit on the base substrate is at least partially located between the orthographic projections of the first sub-segment of the first touch trace and the first sub-segment of the second touch trace on the base substrate.

In an example embodiment of the present disclosure, the display panel further includes:
an encapsulation layer, disposed between the first organic layer and the touch layer, wherein the encapsulation layer includes a first inorganic layer, a second organic layer and a second inorganic layer stacked in a direction away from the base substrate, an orthographic projection of the second organic layer on the base substrate is located on a side of an orthographic projection of the barrier dam on the base substrate away from the second peripheral area.

In an example embodiment of the present disclosure, a distance between the first segment of the first touch trace and the first segment of the second touch trace in a direction parallel to the base substrate is not greater than 20 μm.

In an example embodiment of the present disclosure, the bump unit includes a first bump;
the second region of the first organic layer has a first edge extending in a second direction, the second direction is not parallel with the first direction;
at least a portion of the first edge of the second region of the first organic layer protrudes along the first direction toward the first sub-segment to form at least one of the first bumps.

In an example embodiment of the present disclosure, a dimension of the first bump in the first direction is not less than 35 μm;
in a direction parallel to the base substrate, the shortest distance between an edge of the first bump and the first touch trace or the second touch trace is not less than 4 μm.

In an example embodiment of the present disclosure, the bump unit further includes at least one second bump, the second bump is disposed on a side of the first bump or the second region of the first organic layer away from the base substrate, an orthographic projection of at least a portion of the second bump on the base substrate is located within an orthographic projection of the first bump on the base substrate.

In an example embodiment of the present disclosure, in a direction perpendicular to the base substrate, a sum of heights of the first bump and the second bump is 1.5 μm-2.5 μm.

In an example embodiment of the present disclosure, the bump unit includes a first bump unit, the first bump unit includes a plurality of third bumps;
orthographic projections of the plurality of third bumps on the base substrate do not overlap with the second region of the first organic layer, and the orthographic projections of the plurality of third bumps on the base substrate are located between the first sub-segment of the first touch trace and the first sub-segment of the second touch trace.

In an example embodiment of the present disclosure, the bump unit further includes a second bump unit, the second bump unit is located on a side of the first bump unit in the first direction, and the second bump unit includes a plurality of fourth bumps;
the plurality of fourth bumps are arranged in an array between the first segment of the first touch trace and the first segment of the second touch trace;
orthographic projections of the plurality of fourth bumps on the base substrate are located within the orthographic projection of the second region of the first organic layer on the base substrate.

In an example embodiment of the present disclosure, in a direction perpendicular to the base substrate, a height of the third bumps is 1.5 μm-2.5 μm.

In an example embodiment of the present disclosure, a dimension of the first bump unit in the first direction is not less than 35 μm, and a dimension of the bump unit in the first direction is not greater than 200 μm.

In an example embodiment of the present disclosure, the first segment of the second touch trace is located on a side of the first segment of the first touch trace away from the display area;
the touch layer further includes a ground line, the ground line includes a first main segment and a second main segment extending along the first direction and a bending segment connecting between the first main segment and the second main segment, an orthographic projection of the first main segment on the base substrate does not overlap with the orthographic projection of the second region of the first organic layer on the base substrate, and an orthographic projection of the second main segment on the base substrate is located within the orthographic projection of the second region of the first organic layer on the base substrate;
a maximum distance between the bending segment of the ground line and the first segment of the second touch trace is greater than a maximum distance between the first and second main segments of the ground line and the first segment of the second touch trace.

In an example embodiment of the present disclosure, an orthographic projection of the bending segment on the base substrate intersects with an orthographic projection of an edge of the second region of the first organic layer on the base substrate to form a first angle α, where 0°<α<90°.

In an example embodiment of the present disclosure, the bending segment includes a first bending sub-segment, a second bending sub-segment and a third bending sub-segment connected in sequence, the second bending sub-segment extends along the first direction, the first bending sub-segment connects the first main segment and the second bending sub-segment, and the third bending sub-segment connects the second main segment and the second bending sub-segment;
an orthographic projection of the first bending sub-segment on the base substrate does not overlap with the orthographic projection of the second region of the first organic layer on the base substrate, and an orthographic projection of the third bending sub-segment on the base substrate is located within the orthographic projection of the second region of the first organic layer on the base substrate;
an orthographic projection of the second bending sub-segment on the base substrate intersects with the orthographic projection of the edge of the second region of the first organic layer on the base substrate to form the first angle.

In an example embodiment of the present disclosure, the touch layer further includes a plurality of driving electrodes and a plurality of receiving electrodes, the driving electrodes are configured to receive touch driving signals, the first touch trace is connected with the receiving electrodes for transmitting a mutual capacitance change signal between the driving electrodes and the receiving electrodes;
the second touch trace is configured to apply a shielding signal.

In an example embodiment of the present disclosure, the touch layer further includes a first conductive layer, an insulating layer and a second conductive layer stacked in a direction away from the base substrate;
the first segment of the first touch trace is located in the first conductive layer or the second conductive layer;
the first segment of the second touch trace is located in the first conductive layer or the second conductive layer;
and the first segment of the first touch trace and the first segment of the second touch trace are located in different layers.

In an example embodiment of the present disclosure, each of the first touch trace and the second touch trace further includes a second segment extending along a third direction and connected with the first segment, the third direction is not parallel with the first direction;
the second segment of the first touch trace is distributed in both the first conductive layer and the second conductive layer, orthographic projections of traces of the first touch trace distributed in different conductive layers on the base substrate at least partially overlap, and traces of the first touch trace distributed in different conductive layers are connected through at least one first via hole in the insulating layer;
the second segment of the second touch trace is distributed in both the first conductive layer and the second conductive layer, orthographic projections of traces of the second touch trace distributed in different conductive layers on the base substrate at least partially overlap, and traces of the second touch trace distributed in different conductive layers are connected through at least one second via hole in the insulating layer;
an orthographic projection of the at least one first via hole on the base substrate is located within the orthographic projection of the second segment of the first touch trace on the base substrate;
an orthographic projection of the at least one second via hole on the base substrate is located within the orthographic projection of the second segment of the second touch trace on the base substrate.

In an example embodiment of the present disclosure, the touch layer includes a first conductive layer, an insulating layer and a second conductive layer stacked in a direction away from the base substrate;
the first touch trace is distributed in both the first conductive layer and the second conductive layer, orthographic projections of traces of the first touch trace distributed in different conductive layers on the base substrate at least partially overlap, and traces of the first touch trace distributed in different conductive layers are connected through at least one first via hole in the insulating layer;
the second touch trace is distributed in both the first conductive layer and the second conductive layer, orthographic projections of traces of the second touch trace distributed in different conductive layers on the base substrate at least partially overlap, and traces of the second touch trace distributed in different conductive layers are connected through at least one second via hole in the insulating layer.

In an example embodiment of the present disclosure, each of the first touch trace and the second touch trace further includes a second segment extending along a third direction and connected with the first segment, the third direction is not parallel with the first direction;
an orthographic projection of the at least one first via hole on the base substrate is located within the orthographic projection of the second segment of the first touch trace on the base substrate;
an orthographic projection of the at least one second via hole on the base substrate is located within the orthographic projection of the second segment of the second touch trace on the base substrate.

In an example embodiment of the present disclosure, a line width of the second segment of the first touch trace is greater than a line width of the first segment of the first touch trace;
a line width of the second segment of the second touch trace is greater than a line width of the first segment of the second touch trace.

In an example embodiment of the present disclosure, the display panel further includes a driving chip;
wherein the second peripheral area includes a bonding area, the second region of the first organic layer is at least partially located in the bonding area, and a surface of the second region of the first organic layer away from the base substrate is provided with a groove, the driving chip is located within the groove.

The present disclosure provides a display panel, including:
a base substrate, including a display area and a peripheral area located outside the display area, wherein the peripheral area includes a first peripheral area and a second peripheral area located at a side of the first peripheral area away from the display area;
a first organic layer, disposed on a side of the base substrate, wherein the first organic layer includes a second region, the second region is located in the second peripheral area;
a barrier dam, disposed on a side of the base substrate, wherein the barrier dam is located in the first peripheral area;
a touch layer, disposed on a side of the first organic layer away from the base substrate, wherein the touch layer includes a first touch trace and a second touch trace, each of the first touch trace and the second touch trace includes a first segment extending in a first direction, each of the first segments of the first touch trace and the second touch trace is located in the second peripheral area;
wherein each of the first segments of the first touch trace and the second touch trace includes a first sub-segment and a second sub-segment connected to each other, the first sub-segment and the second sub-segment of the first touch trace are at different distances from the base substrate, and the first sub-segment and the second sub-segment of the second touch trace are at different distances from the base substrate;
orthographic projections of the first sub-segments of the first touch trace and the second touch trace on the base substrate do not overlap with an orthographic projection of the first organic layer on the base substrate;
orthographic projections of the second sub-segments of the first touch trace and the second touch trace on the base substrate are located within an orthographic projection of the second region of the first organic layer on the base substrate;
wherein the touch layer further includes a first conductive layer, an insulating layer and a second conductive layer stacked in a direction away from the base substrate, the first segment of the first touch trace is located in the first conductive layer or the second conductive layer, the first segment of the second touch trace is located in the first conductive layer or the second conductive layer, and the first segment of the first touch trace and the first segment of the second touch trace are located in different layers.

In an example embodiment of the present disclosure, each of the first touch trace and the second touch trace further includes a second segment extending along a third direction and connected with the first segment, the third direction is not parallel with the first direction;
the second segment of the first touch trace is distributed in both the first conductive layer and the second conductive layer, orthographic projections of traces of the first touch trace distributed in different conductive layers on the base substrate at least partially overlap, and traces of the first touch trace distributed in different conductive layers are connected through at least one first via hole in the insulating layer;
the second segment of the second touch trace is distributed in both the first conductive layer and the second conductive layer, orthographic projections of traces of the second touch trace distributed in different conductive layers on the base substrate at least partially overlap, and traces of the second touch trace distributed in different conductive layers are connected through at least one second via hole in the insulating layer;
an orthographic projection of the at least one first via hole on the base substrate is located within the orthographic projection of the second segment of the first touch trace on the base substrate;
an orthographic projection of the at least one second via hole on the base substrate is located within the orthographic projection of the second segment of the second touch trace on the base substrate.

The present disclosure further provides a display panel, including:
a base substrate, including a display area and a peripheral area located outside the display area, wherein the peripheral area includes a first peripheral area and a second peripheral area located at a side of the first peripheral area away from the display area;
a first organic layer, disposed on a side of the base substrate, wherein the first organic layer includes a second region, the second region is located in the second peripheral area;
a barrier dam, disposed on a side of the base substrate, wherein the barrier dam is located in the first peripheral area;
a touch layer, disposed on a side of the first organic layer away from the base substrate, wherein the touch layer includes a second touch trace, the second touch trace includes a first segment extending in a first direction, the first segment of the second touch trace is located in the second peripheral area;
the touch layer further includes a signal line, wherein the signal line is located on a side of the second touch trace away from the display area;
the signal line includes a first main segment and a second main segment extending along the first direction and a bending segment connecting between the first main segment and the second main segment, an orthographic projection of the first main segment on the base substrate does not overlap with the orthographic projection of the second region of the first organic layer on the base substrate, and an orthographic projection of the second main segment on the base substrate is located within the orthographic projection of the second region of the first organic layer on the base substrate;
a maximum distance between the bending segment of the signal line and the first segment of the second touch trace is greater than a maximum distance between the first and second main segments of the signal line and the first segment of the second touch trace.

In an example embodiment of the present disclosure, an orthographic projection of the bending segment on the base substrate intersects with an orthographic projection of an edge of the second region of the first organic layer on the base substrate to form a first angle α, where 0°<α<90°.

In an example embodiment of the present disclosure, the bending segment includes a first bending sub-segment, a second bending sub-segment and a third bending sub-segment connected in sequence, the second bending sub-segment extends along the first direction, the first bending sub-segment connects the first main segment and the second bending sub-segment, and the third bending sub-segment connects the second main segment and the second bending sub-segment;
an orthographic projection of the first bending sub-segment on the base substrate does not overlap with the orthographic projection of the second region of the first organic layer on the base substrate, and an orthographic projection of the third bending sub-segment on the base substrate is located within the orthographic projection of the second region of the first organic layer on the base substrate.

In an example embodiment of the present disclosure, an orthographic projection of the bending segment on the base substrate intersects with an orthographic projection of an edge of the second region of the first organic layer on the base substrate to form a first angle α, where 0°<α<90°;
wherein the bending segment includes a first bending sub-segment, a second bending sub-segment and a third bending sub-segment connected in sequence, the second bending sub-segment extends along the first direction, the first bending sub-segment connects the first main segment and the second bending sub-segment, and the third bending sub-segment connects the second main segment and the second bending sub-segment;
an orthographic projection of the first bending sub-segment on the base substrate does not overlap with the orthographic projection of the second region of the first organic layer on the base substrate, and an orthographic projection of the third bending sub-segment on the base substrate is located within the orthographic projection of the second region of the first organic layer on the base substrate;
an orthographic projection of the second bending sub-segment on the base substrate intersects with the orthographic projection of the edge of the second region of the first organic layer on the base substrate to form the first angle.

In an example embodiment of the present disclosure, the signal line is used to apply a ground signal.

In an example embodiment of the present disclosure, the first organic layer further includes a first region, the first region is located in the first peripheral area, and the barrier dam includes the first region of the first organic layer.

According to a second aspect of the present disclosure, a display device is provided, including the display panel described above.

In the display panel provided by the present disclosure, each of the first touch trace and the second touch trace includes a first segment extending along a first direction, and the first segment is located in the second peripheral area of the base substrate. Each of the first segments of the first touch trace and the second touch trace includes a first sub-segment and a second sub-segment connected to each other, wherein orthographic projections of the first sub-segments and the first organic layer on the base substrate do not overlap, and orthographic projections of the second sub-segments on the base substrate are located within an orthographic projection of the second region of the first organic layer on the base substrate. That is, the first and second sub-segments have different distances from the base substrate, resulting in a height difference. The first organic layer of the present disclosure also includes a bump unit, and the orthographic projection of the bump unit on the base substrate is at least partially located between the first sub-segment of the first touch trace and the first sub-segment of the second touch trace, that is, the bump unit separates the first sub-segments of the first touch trace and the second touch trace, which facilitates reducing the risk of short circuits between the two touch traces during etching to a certain extent, thereby improving the quality of the display panel.

### DESCRIPTION OF THE DRAWINGS

The above and other features and advantages of the present disclosure will become more apparent through a detailed description of example embodiments thereof with reference to the accompanying drawings.

FIG. 1 is a schematic structural diagram of the base substrate in an example embodiment of the present disclosure;

FIG. 2 is a schematic cross-sectional view of the display area of the display panel in an example embodiment of the present disclosure;

FIG. 3 is a schematic diagram of the planar structure of the touch layer in an example embodiment of the present disclosure;

FIG. 4 is a schematic structural diagram of an embodiment of traces of section A in FIG. 3;

FIG. 5 is a schematic structural diagram of the peripheral area of the first organic layer in an example embodiment of the present disclosure;

FIG. 6 is a schematic structural diagram of the barrier dam in an example embodiment of the present disclosure;

FIG. 7 is a schematic structural diagram of an embodiment of section B in FIG. 4;

FIG. 8 is a schematic cross-sectional view of the bump unit in FIG. 7;

FIG. 9 is an enlarged schematic diagram of section C1 in FIG. 7;

FIG. 10 is an enlarged schematic diagram of section D in FIG. 4;

FIG. 11 is another schematic structural diagram of an embodiment of section B in FIG. 4;

FIG. 12 is a schematic cross-sectional view of the bump unit in FIG. 11;

FIG. 13 is still another schematic structural diagram of an embodiment of section B in FIG. 4;

FIG. 14 is a schematic cross-sectional view of the bump unit in FIG. 13;

FIG. 15 is still another schematic structural diagram of an embodiment of section B in FIG. 4;

FIG. 16 is still another schematic structural diagram of an embodiment of section B in FIG. 4;

FIG. 17 is an enlarged schematic view of section C2 in FIG. 16;

FIG. 18 is a schematic cross-sectional view of the bump unit in FIG. 16;

FIG. 19 is another schematic structural diagram of an embodiment of traces of section A in FIG. 3;

FIG. 20 is an enlarged schematic view of section E in FIG. 19;

FIG. 21 is a schematic diagram of connections of traces distributed in different conductive layers in an example embodiment of the present disclosure.

The reference numerals of main components in the figure are illustrated as follows: 100—base substrate; 110—display area; 120—peripheral area; 121—first peripheral area; 122—second peripheral area; 1221—bonding area; 200—driving circuit layer; 201—active layer; 202—first gate insulation layer; 203—first gate metal layer; 204—second gate insulation layer; 205—second gate metal layer; 206—interlayer dielectric layer; 207—first source/drain layer; 208—first planarization layer; 209—second source/drain layer; 210—second planarization layer; 211—light shielding layer; 212—passivation layer; 300—light emitting layer; 301—first organic layer; 302—first electrode layer; 303—light emitting functional layer; 304—second electrode layer; 011—pixel definition area; 012—pixel opening; 013—isolation pillar; 014—first region; 015—second region; 015a—groove; 015b—first edge; 016—bump unit; 161—first bump; 162—second bump; 163—first bump unit; 164—third bump; 165—second bump unit; 166—fourth bump; 400—encapsulation layer; 401—first inorganic layer; 402—second organic layer; 403—second inorganic layer; 500—touch layer; 501—first conductive layer; 502—insulating layer; 503—second conductive layer; 504—buffer layer; 505—protective layer; 506—driving electrode; 507—driving electrode group; 508—receiving electrode; 509—receiving electrode group; 510—first bridging line; 511—second bridging line; 512—driving touch trace; 513—receiving touch trace; 514—first touch trace; 514a—first segment; 14a1—first sub-segment; 14a2—second sub-segment; 514b—second segment; 514c—first via hole; 515—second touch trace; 515a—first segment; 15a1—first sub-segment; 15a2—second sub-segment; 515b—second segment; 515c—second via hole; 516—ground line; 516a—first main segment; 516b—second main segment; 516c—bending segment; 16c1—first bending sub-segment; 16c2—second bending sub-segment; 16c3—third bending sub-segment; 600—driving chip; 700—blocking dam.

### DETAILED DESCRIPTION

The example embodiments will now be described more fully with reference to the accompanying drawings. However, the example embodiments can be implemented in a variety of forms and should not be construed as being limited to the embodiments described herein; rather, these embodiments are provided so that the present disclosure will be comprehensive and complete and the concept of the example embodiments will be fully conveyed to those skilled in the art. The described features, structures, or characteristics may be combined in any suitable manner in one or more embodiments. In the following description, numerous specific details are provided to provide a thorough understanding of the embodiments of the present disclosure.

In the figures, the thickness of regions and layers may be exaggerated for clarity. Identical reference numerals in the figures represent identical or similar structures, and their detailed descriptions will be omitted.

The described features, structures, or characteristics may be combined in any suitable manner in one or more embodiments. In the following description, numerous specific details are provided to provide a thorough understanding of the embodiments of the present disclosure. However, those skilled in the art will appreciate that the technical solutions of the present disclosure can be practiced without one or more of the specific details, or that other methods, components, materials, etc. may be employed. In other instances, well-known structures, materials, or operations are not shown or described in detail to avoid obscuring the main technical concepts of the present disclosure.

When a structure is referred to as “on” another structure, it may mean that the structure is integrally formed on the other structure, or the structure is “directly” disposed on the other structure, or the structure is “indirectly” disposed on the other structure via another structure.

The terms “a”, “an” and “the” are used to indicate the presence of one or more elements/components; the terms “including” and “having” are used to indicate an open-ended inclusive meaning and indicate that additional elements/components/etc. may also be present in addition to the listed elements/components/etc. The terms “first” and “second” etc. are used only as labels and do not limit the number of the objects.

In related art, in ultra-narrow bezel designs for display panels, some touch traces located at the bottom bezel of the display panel are positioned outside the barrier dam (used to block water and oxygen) of the display panel. Different locations of these touch traces have different distances from the base substrate of the display panel, and have a height difference. Therefore, when such touch traces are formed by etching, it can easily produce etch remains, resulting in short circuits between adjacent two touch traces.

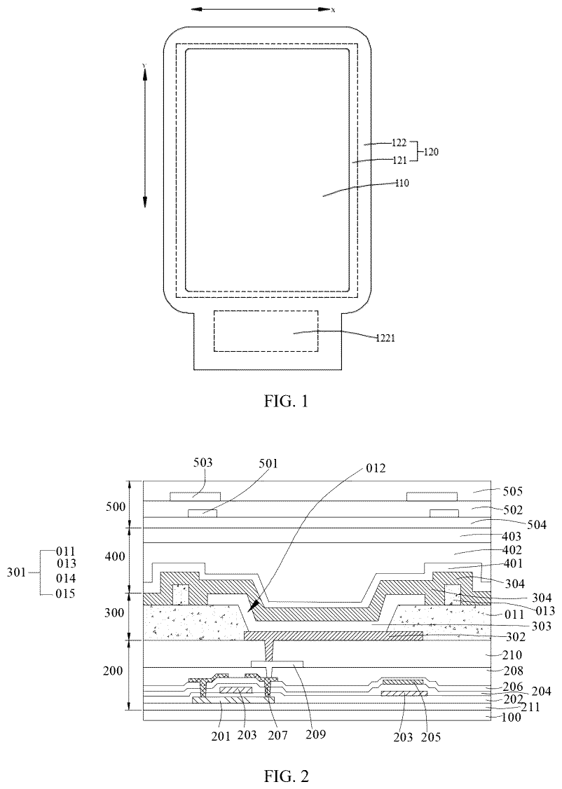

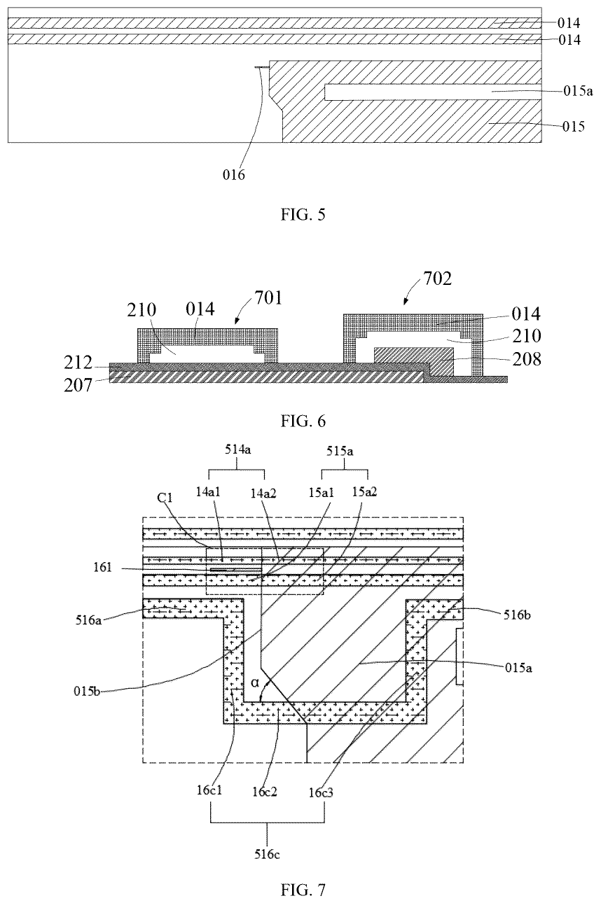

As shown in FIGS. 1 to 7 and 10, the present disclosure provides a display panel, including a base substrate 100, a first organic layer 301, a barrier dam 700 and a touch layer 500, wherein the base substrate 100 includes a display area 110 and a peripheral area 120 located outside the display area 110, the peripheral area 120 includes a first peripheral area 121 and a second peripheral area 122 located at a side of the first peripheral area 121 away from the display area 110; the first organic layer 301 is disposed on a side of the base substrate 100, the first organic layer 301 includes a second region 015, and further includes a first region 014, the first region 014 is located in the first peripheral area 121, the second region 015 is located in the second peripheral area 122; the barrier dam 700 is disposed on a side of the base substrate 100, the barrier dam 700 is located in the first peripheral area 121, the barrier dam 700 includes a first region 014 of the first organic layer 301; the touch layer 500 is disposed on a side of the first organic layer 301 away from the base substrate 100, the touch layer 500 includes a first touch trace 514 and a second touch trace 515, each of the first touch trace 514 and the second touch trace 515 includes a first segment 514a or 515a extending in a first direction X, each of the first segments 514a or 515a of the first touch trace 514 and the second touch trace 515 is located in the second peripheral area 122; wherein each of the first segments 514a or 515a of the first touch trace 514 and the second touch trace 515 includes a first sub-segment 14a1 or 15a1 and a second sub-segment 14a2 or 15a2 connected to each other, the first sub-segment 14a1 or 15a1 and the second sub-segment 14a2 or 15a2 of the first touch trace 514 are at different distances from the base substrate 100, and the first sub-segment 14a1 or 15a1 and the second sub-segment 14a2 or 15a2 of the second touch trace 515 are at different distances from the base substrate 100; orthographic projections of the first sub-segments 14a1 or 15a1 of the first touch trace 514 and the second touch trace 515 on the base substrate 100 do not overlap with an orthographic projection of the first organic layer 301 on the base substrate 100; orthographic projections of the second sub-segments 14a2 or 15a2 of the first touch trace 514 and the second touch trace 515 on the base substrate 100 are located within an orthographic projection of the second region 015 of the first organic layer 301 on the base substrate 100; the first organic layer 301 further includes a bump unit 016, an orthographic projection of the bump unit 016 on the base substrate 100 is at least partially located between the orthographic projections of the first sub-segment 14a1 or 15a1 of the first touch trace 514 and the first sub-segment 14a1 or 15a1 of the second touch trace 515 on the base substrate 100.

In the display panel provided by the present disclosure, each of the first touch trace 514 and the second touch trace 515 includes a first segment 514a or 515a extending in a first direction X, the segment is located in the second peripheral area 122 of the base substrate 100. Each of the first segments 514a or 515a of the first touch trace 514 and the second touch trace 515 includes a first sub-segment 14a1 or 15a1 and a second sub-segment 14a2 or 15a2 connected to each other, wherein orthographic projections of the first sub-segment 14a1 or 15a1 and the first organic layer 301 on the base substrate 100 do not overlap, and the orthographic projection of the second sub-segment 14a2 or 15a2 on the base substrate 100 is located within the orthographic projection of the second region 015 of the first organic layer 301 on the base substrate 100, that is, the first sub-segment 14a1 or 15a1 and the second sub-segment 14a2 or 15a2 are at different distances from the base substrate 100, and there is a height difference. The first organic layer 301 of the present disclosure also includes a bump unit 016, and the orthographic projection of the bump unit 016 on the base substrate 100 is at least partially located between the first sub-segment 14a1 or 15a1 of the first touch trace 514 and the first sub-segment 14a1 or 15a1 of the second touch trace 515, that is, the bump unit 016 separates the first sub-segment 14a1 or 15a1 of the first touch trace 514 and the second touch trace 515, which facilitates reducing the risk of short circuits between the two touch traces during etching to a certain extent, thereby improving the quality of the display panel.

The following describes various components of the display panel provided by the present disclosure in detail, with reference to the accompanying drawings and specific embodiments.

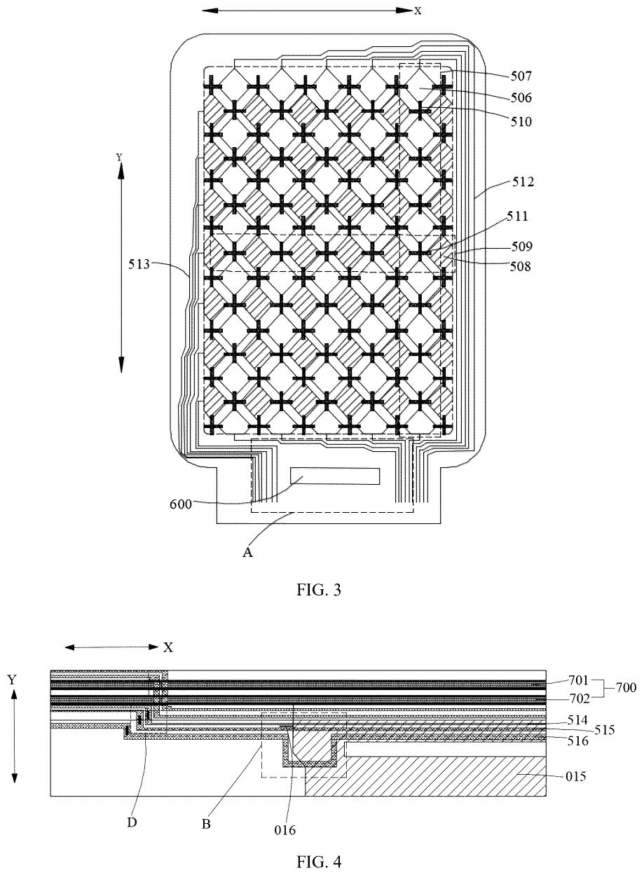

As shown in FIGS. 1 to 7 and FIG. 10, FIG. 4 is a schematic diagram of an example partial structure of section A in FIG. 3, and FIG. 7 is an example enlarged view of section B in FIG. 4. The display panel provided by the present disclosure can be an OLED (Organic Light emitting Diode) display panel, a Micro LED (Micro Light emitting Diode) display panel, a Mini LED (Mini Light emitting Diode) display panel, or a QLED (Quantum Dots Light emitting Diode) display panel. The display panel includes a base substrate 100, a first organic layer 301, a barrier dam 700 and a touch layer 500.

As shown in FIG. 1, the base substrate 100 can be made of glass materials such as soda-lime glass, quartz glass, sapphire glass, or can be made of metal materials such as stainless steel, aluminum, nickel. The base substrate 100 can also be a flexible base substrate. For example, in one embodiment of the present disclosure, the base substrate 100 can be made of polyimide (PI). The base substrate 100 can also be a composite of a plurality of layers. For example, in one embodiment of the present disclosure, the base substrate 100 can include a bottom film, a pressure-sensitive adhesive layer, a first polyimide layer and a second polyimide layer stacked in sequence.

The base substrate 100 includes a display area 110 and a peripheral area 120 located outside the display area 110. The peripheral area 120 includes a first peripheral area 121 and a second peripheral area 122 located on a side of the first peripheral area 121 away from the display area 110. In some embodiments of the present disclosure, the second peripheral area 122 also includes a bonding area 1221.

As shown in FIG. 2, a first organic layer 301 is disposed on a side of the base substrate 100. In some embodiments of the present disclosure, the display panel also includes a driving circuit layer 200 and a light emitting layer 300. The light emitting layer 300 includes the first organic layer 301 and a plurality of light emitting devices. The driving circuit layer 200 is disposed between the base substrate 100 and the light emitting layer 300.

The driving circuit layer 200 includes a driving circuit for driving the light emitting devices to emit light. This driving circuit includes pixel circuits located in the display area 110 and peripheral circuits located in the peripheral area 120. A plurality of pixel circuits are provided, which are used to drive the light emitting devices to emit light in a one-to-one correspondence. These pixel circuits can be 7T1C, 7T2C, 6TIC, or 6T2C pixel circuits, as long as they can drive the light emitting devices to emit light. Their structure is not particularly limited. The number of pixel circuits is the same as the number of light emitting devices, and they are connected to each light emitting device in a one-to-one correspondence, to control each light emitting device to emit light respectively. Here, nTmC indicates that a pixel circuit includes n transistors (represented by the letter “T”) and m capacitors (represented by the letter “C”).

The peripheral circuit is located in the peripheral area 120 and is connected to the pixel circuits to input driving signals to the pixel circuits, to control the light emitting devices to emit light. The peripheral circuit may include a gate driving circuit and a light emitting control circuit, and may also include other circuits. The specific structure of the peripheral circuit is not specifically limited here.

Taking the transistor in the driving circuit as a top-gate thin-film transistor as an example, the driving circuit layer 200 includes an active layer 201, a first gate insulating layer 202, a first gate metal layer 203, a second gate insulating layer 204, a second gate metal layer 205, an interlayer dielectric layer 206, a first source/drain layer 207, a first planarization layer 208, a second source/drain layer 209 and a second planarization layer 210.

The active layer 201 is disposed on a side of the base substrate 100; the first gate insulating layer 202 is disposed on the side of the active layer 201 away from the base substrate 100, the first gate insulating layer 202 covers the active layer 201; the first gate metal layer 203 is disposed on the side of the first gate insulating layer 202 away from the base substrate 100, the first gate metal layer 203 may include the gate electrode of the transistor and the first plate of the capacitor. A second gate insulating layer 204 is disposed on a side of the first gate metal layer 203 away from the base substrate 100, and the second gate insulating layer 204 covers the first gate metal layer 203; the second gate metal layer 205 is disposed on a side of the second gate insulating layer 204 away from the base substrate 100, and the second gate metal layer 205 may include a second plate of a capacitor, and an interlayer dielectric layer 206 is disposed on a side of the second gate insulating layer 204 away from the base substrate 100; a first source/drain layer 207 is disposed on a side of the interlayer dielectric layer 206 away from the base substrate 100, and the first source/drain layer 207 includes a source electrode and a drain electrode of the transistor, and the source electrode and the drain electrode are connected to the active layer 201. A first planarization layer 208 is disposed on a side of the first source/drain layer 207 away from the base substrate 100, a second source/drain layer 209 is disposed on a side of the first planarization layer 208 away from the base substrate 100, and a second planarization layer 210 is disposed on a side of the second source/drain layer 209 away from the base substrate 100. Further, the driving circuit layer 200 also includes a light shielding layer 211 and a passivation layer 212, or the like. The light shielding layer 211 is disposed between the base substrate 100 and the active layer 201. The passivation layer 212 (FIG. 6) is disposed between the first source/drain layer 207 and the first planarization layer 208.

As shown in FIGS. 1 to 3 and 5, the light emitting layer 300 is disposed between the driving circuit layer 200 and the touch layer 500, the light emitting layer 300 includes a first organic layer 301. The first organic layer 301 includes a pixel definition area 011, which is at least partially located in the display area 110. The pixel definition area 011 contains a plurality of pixel openings 012, each of which defines the area of a light emitting device. The shape of the pixel opening 012, i.e., the shape of the outline of the orthographic projection of the pixel opening 012 on the base substrate 100, can be a polygon, a smooth closed curve, or other shapes, which is not specifically limited here.

The first organic layer 301 also includes isolation pillars 013, which are located on the side of the pixel definition area 011 away from the base substrate 100. There are a plurality of isolation pillars 013, and the orthographic projections of the isolation pillars on the base substrate 100 are located within the orthographic projection of the pixel definition area 011 on the base substrate 100.

The first organic layer 301 also includes a first region 014 and a second region 015. The first region 014 is located in the first peripheral area 121, and the second region 015 is located in the second peripheral area 122. Further, the second region 015 of the first organic layer 301 is at least partially located in the bonding area 1221. The display panel also includes a driving chip 600. A groove 015a is provided on the surface of the second region 015 of the first organic layer 301 away from the base substrate 100. The driving chip 600 is located within the groove 015a. In this embodiment, the groove 015a in the second region 015 of the first organic layer 301 facilitates reducing the bending stress during bonding, thereby improving the bonding yield.

Taking an OLED light emitting device as an example, the light emitting device includes a first electrode layer 302, a light emitting functional layer 303 and a second electrode layer 304 that are sequentially arranged in a direction away from the base substrate 100. The first electrode layer 302 can serve as the anode layer of the light emitting device. The light emitting functional layer 303 covers the first electrode layer 302, and the second electrode layer 304 covers the light emitting functional layer 303. The first electrode layer 302 can be connected to the source/drain electrode of the transistor. The second electrode layer 304 can cover the light emitting functional layer 303 and can serve as the cathode layer of the light emitting device. The second electrode layer 304 can have a single-layer or multi-layer structure, and its material can include one or more of conductive metals, metal oxides and alloys. The light emitting functional layer 303 is at least partially disposed within the pixel opening 012, and may include a hole injection layer, a hole transport layer, a light emitting material layer, an electron transport layer and an electron injection layer that are stacked sequentially in a direction away from the base substrate 100. The holes and electrons recombine in the light emitting material layer to form excitons, and the excitons radiate photons, thereby generating visible light. The light emitting material layer is an organic light emitting material layer, and the specific light emitting principle is not described in detail here.

The light emitting device may also be a QLED light emitting device. Different from an OLED light emitting device, the light emitting material layer is a quantum dot light emitting material layer.

As shown in FIGS. 1 to 6, the first organic layer 301 further includes a first region 014 and a second region 015. The first region 014 is located in the first peripheral area 121, and the second region 015 is located in the second peripheral area 122. The first region 014 of the first organic layer 301 may surround the periphery of the pixel definition area 011. A barrier dam 700 is provided on a side of the base substrate 100. This barrier dam is used to block water and oxygen, to protect the light emitting devices, transistors and other components in the display area 110 from corrosion by external water and oxygen. The barrier dam 700 is located in the first peripheral area 121 and the barrier dam 700 includes the first region 014 of the first organic layer 301.

As shown in FIGS. 4, 5, and 6, in some embodiments of the present disclosure, there may be a plurality of barrier dams 700. For example, there may be two barrier dams 700, one of which is a first barrier dam 701, and the other is a second barrier dam 702. The second barrier dam 702 surrounds the periphery of the first barrier dam 701, that is, surrounds the side of the first barrier dam 701 away from the display area 110. In addition to including the first region 014 of the first organic layer 301, the barrier dam 700 may also include other film layers, such as portions of the first planarization layer 208 or the second planarization layer 210. The film layers included in different barrier dams 700 may vary. For example, the first barrier dam 701 includes not only the first region 014 of the first organic layer 301, but also portions of the first planarization layer 208, while the second barrier dam 702 includes not only the second region 015 of the first organic layer 301, but also portions of the first planarization layer 208 and the second planarization layer 210.

As shown in FIGS. 2, 3, and 4, in some embodiments of the present disclosure, the display panel further includes an encapsulation layer 400, which is disposed between the first organic layer 301 and the touch layer 500, specifically between the light emitting layer 300 and the touch layer 500. The encapsulation layer 400 can be used to protect the light emitting layer 300 and prevent external water and oxygen from corroding the light emitting device. In some embodiments of the present disclosure, encapsulation can be achieved using a thin-film encapsulation (TFE) manner. Specifically, the encapsulation layer 400 may include a first inorganic layer 401, a second organic layer 402, and a second inorganic layer 403 that are stacked in a direction away from the base substrate 100. The first inorganic layer 401 covers the surface of the light emitting layer 300 away from the base substrate 100. The second organic layer 402 may be disposed on the surface of the first inorganic layer 401 away from the base substrate 100, and the boundary of the second organic layer 402 is defined inward of the boundary of the first inorganic layer 401. The second inorganic layer 403 covers the second organic layer 402 and the first inorganic layer 401 not covered by the second organic layer 402. The second inorganic layer 403 blocks the intrusion of water and oxygen, and the flexible second organic layer 402 achieves planarization. The orthographic projection of the second organic layer 402 on the base substrate 100 is located on the side of the orthographic projection of the barrier dam 700 on the base substrate 100 away from the second peripheral area 122. Further, the barrier dam 700 may also include partial regions of the first inorganic layer 401 and the second inorganic layer 403. The partial regions of the first inorganic layer 401 and the second inorganic layer 403 included in the barrier dam 700 may wrap the other film layers of the barrier dam 700.

The touch layer 500 is disposed on the side of the first organic layer 301 away from the base substrate 100, specifically on the side of the encapsulation layer 400 away from the base substrate 100. The touch layer 500 includes a first conductive layer 501, an insulating layer 502 and a second conductive layer 503 that are stacked in a direction away from the base substrate 100. The touch layer 500 also includes a plurality of driving electrodes 506 and a plurality of receiving electrodes 508, the plurality of driving electrodes 506 and the plurality of receiving electrodes 508 are arranged in an array at intervals. The plurality of driving electrodes 506 are arranged along the third direction YY and interconnected to form a driving electrode group 507. The plurality of receiving electrodes 508 are arranged along the first direction XX and interconnected to form a receiving electrode group 509. The driving electrode group 507 and the receiving electrode group 509 are insulated from each other. The orthographic projections of the driving electrodes 506 and the receiving electrodes 508 on the base substrate 100 are approximately diamond-shaped. Further, the driving electrodes 506 and the receiving electrodes 508 are disposed on the same layer, i.e., the driving electrodes 506 and the receiving electrodes 508 are formed using the same material and process. The driving electrodes 506 and the receiving electrodes 508 are grid-shaped electrode blocks. A plurality of driving electrodes 506 and a plurality of receiving electrodes 508 are arranged alternately to form a checkerboard structure. Adjacent two driving electrodes 506 in the driving electrode group 507 can be connected via a first bridging line 510, and adjacent two receiving electrodes 508 in the receiving electrode group 509 can be connected via a second bridging line 511. The first bridging line 510 and the second bridging line 511 are disposed in different conductive layers, and the orthographic projections of the first bridging line 510 and the second bridging line 511 on the base substrate 100 at least partially overlap.

In one embodiment, the driving electrodes 506, the receiving electrodes 508 and the first bridging line 510 are distributed in the first conductive layer 501, and the second bridging line 511 is distributed in the second conductive layer 503. In another embodiment, the first bridging line 510 is distributed in the first conductive layer 501, and the driving electrodes 506, the receiving electrodes 508, and the second bridging line 511 are distributed in the first conductive layer 501.

When the finger of a user touches the touchable area of the display panel, the mutual capacitance between the driving electrode group 507 and the receiving electrode group 509 that are insulated and intersected at the touch point changes. The driving circuit scans the driving electrode group 507 in the receiving electrode group 509 and the driving electrode group 507 one by one, reads the signals from the detection electrode group in each driving electrode group 507 and receiving electrode group 509 when scanning one driving electrode group 507. After one round of scanning, the coordinates of the touch points are determined, and the corresponding content response to the touch operation is performed based on the coordinates of the touch points.

The touch layer 500 also includes a driving touch trace 512 and a receiving touch trace 513. The driving touch trace 512 can be connected to the driving electrode group 507, and the receiving touch trace 513 can be connected to the receiving electrode group 509. Further, the touch layer 500 also includes a first touch trace 514 and a second touch trace 515. The first touch trace 514 is the receiving touch trace 513, connected to the receiving electrode 508 and used to transmit the mutual capacitance change signal between the driving electrode 506 and the receiving electrode 508. The second touch trace 515 is used to apply a shielding signal. The second touch trace 515 is located on the side of the first touch trace 514 away from the display area 110. Further, the touch layer 500 also includes a ground line 516, which is located on the side of the second touch trace 515 away from the display area 110.

Further, the first touch trace 514 is the outermost of all receiving touch traces 513, i.e., the receiving touch trace 513 farthest from the display area 110 in a direction parallel to the base substrate 100. The second touch trace 515 is located between the first touch trace 514 and the ground line 516, and is used to apply a shielding signal to prevent signal interference between the first touch trace 514 and the ground line 516. Specifically, the second touch trace 515 can apply a touch driving signal.

Both the first touch trace 514 and the second touch trace 515 include a first segment 514a or 515a extending along the first direction X. The first segments 514a or 515a of the first touch trace 514 and the second touch trace 515 are located in the second peripheral area 122. In some embodiments of the present disclosure, the distance between the first segment 514a of the first touch trace 514 and the first segment 515a of the second touch trace 515 in a direction parallel to the base substrate 100 is not greater than 20 μm.

As shown in FIGS. 4 and 7, the first segments 514a or 515a of the first touch trace 514 and the second touch trace 515 include a first sub-segment 14a1 or 15a1 and a second sub-segment 14a2 or 15a2 connected to each other. The first sub-segment 14a1 and the second sub-segment 14a2 of the first touch trace 514 are at different distances from the base substrate 100. The first sub-segment 15a1 and the second sub-segment 15a2 of the second touch trace 515 are at different distances from the base substrate 100. That is, the first sub-segment 14a1 and the second sub-segment 14a2 of the first touch trace 514 have a height difference relative to the base substrate 100, and the first sub-segment 15a1 and the second sub-segment 15a2 of the second touch trace 515 have a height difference relative to the base substrate 100.

Specifically, the orthographic projections of the first sub-segments 14a1 or 15a1 of the first touch trace 514 and the second touch trace 515 on the base substrate 100 do not overlap with the orthographic projection of the first organic layer 301 on the base substrate 100; and the orthographic projections of the second sub-segments 14a2 or 15a2 of the first touch trace 514 and the second touch trace 515 on the base substrate 100 are located within the orthographic projection of the second region 015 of the first organic layer 301 on the base substrate 100.

The first organic layer 301 also includes a bump unit 016. The orthographic projection of the bump unit 016 on the base substrate 100 is at least partially located between the orthographic projections of the first sub-segment 14a1 or 15a1 of the first touch trace 514 and the first sub-segment 14a1 or 15a1 of the second touch trace 515 on the base substrate 100. Further, the bump unit 016 can be located at the junction of the first sub-segment 14a1 or 15a1 and the second sub-segment 14a2 or 15a2. In this way, it separates the first sub-segments 14a1 or 15a1 of the first touch trace 514 and the second touch trace 515 at a height difference, thereby reducing the risk of short circuits between them two.

The bump unit 016 can be arranged in various ways. The following describes various embodiments to illustrate the arrangement of the bump unit 016.

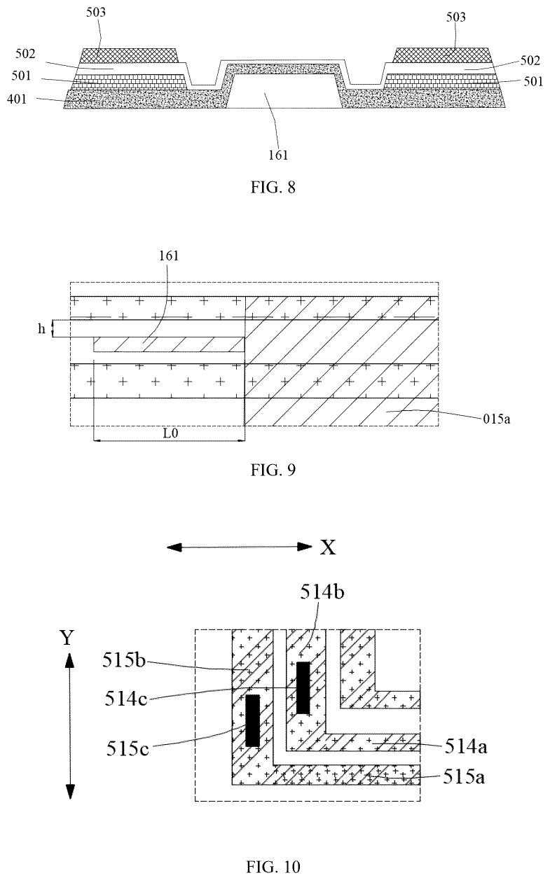

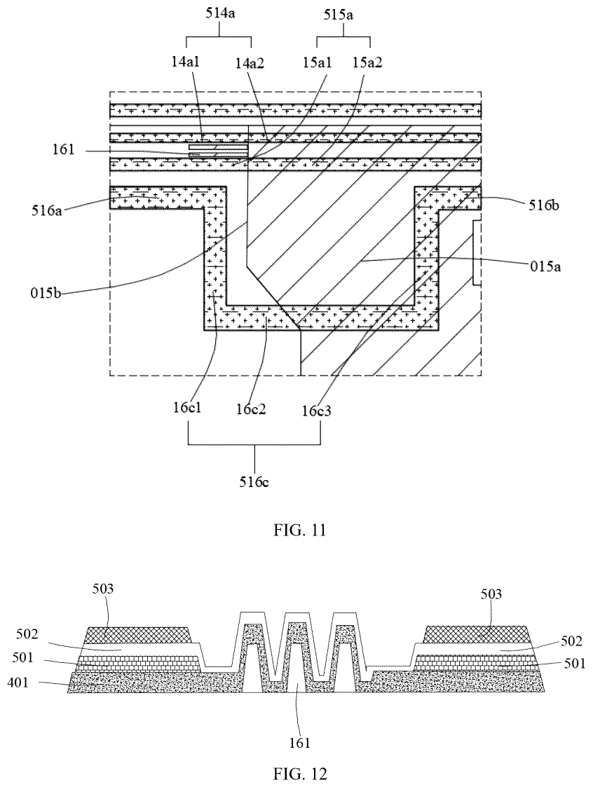

As shown in FIGS. 7, 8, 9, 11, and 12, FIG. 12 is a cross-sectional view of the bump unit 016 in FIG. 11 along the third direction Y. In some embodiments of the present disclosure, the bump unit 016 includes a first bump 161. The second region 015 of the first organic layer 301 has a first edge 015b extending along the second direction X0, the second direction XO is not parallel with the first direction X. The angle between the second direction XO and the first direction X can be greater than 0° and less than or equal to 90°. At least a portion of the first edge 015b of the second region 015 of the first organic layer 301 protrudes along the first direction X toward the first sub-segment 14a1 or 15a1, forming at least one first bump 161. The number of first bumps 161 can be one or more. When there are a plurality of first bumps 161, the plurality of first bumps 161 can be arranged sequentially along the third direction Y, the third direction Y is substantially perpendicular to the first direction X.

The orthographic projection of the first bump 161 on the base substrate 100 can have various shapes, including a rectangle, an ellipse, or a polygon, which is not specifically limited. Preferably, the orthographic projection of the first bump 161 on the base substrate 100 is approximately rectangular. Further, the cross-section of the first bump 161 perpendicular to the base substrate 100 can be rectangular, a regular trapezoid, an inverted trapezoid, or an irregular shape with an arc-shaped or pointed top, etc.

The size of the first bump 161 can also vary. For example, the dimension of the first bump 161 in the first direction X is not less than 35 μm. That is, the length L0 of the first edge 015b of the second region 015 of the first organic layer 301 protruding along the first direction X toward the first sub-segment 14a1 or 15a1 is not less than 35 μm. In a direction parallel to the base substrate 100, the shortest distance h between the edge of the first bump 161 and the first touch trace 514 or the second touch trace 515 is not less than 4 μm. As shown in FIG. 7, when the bump unit 016 includes only one first bump 161, the distance between the first bump 161 and the first touch trace 514 is not less than 4 μm, and the distance between the first bump 161 and the second touch trace 515 is also not less than 4 μm. As shown in FIG. 11, when the bump unit 016 includes a plurality of first bumps 161, the distance between the first bump 161 closest to the first touch trace 514 and the first touch trace 514 is not less than 4 μm, and the distance between the first bump 161 closest to the second touch trace 515 and the second touch trace 515 is not less than 4 μm. In this embodiment, the size restriction on the first bump 161 is intended to prolong the path for a short circuit that might occur during etching of the first touch trace 514 and the second touch trace 515, thereby further reducing the risk of a short circuit at the corresponding location.

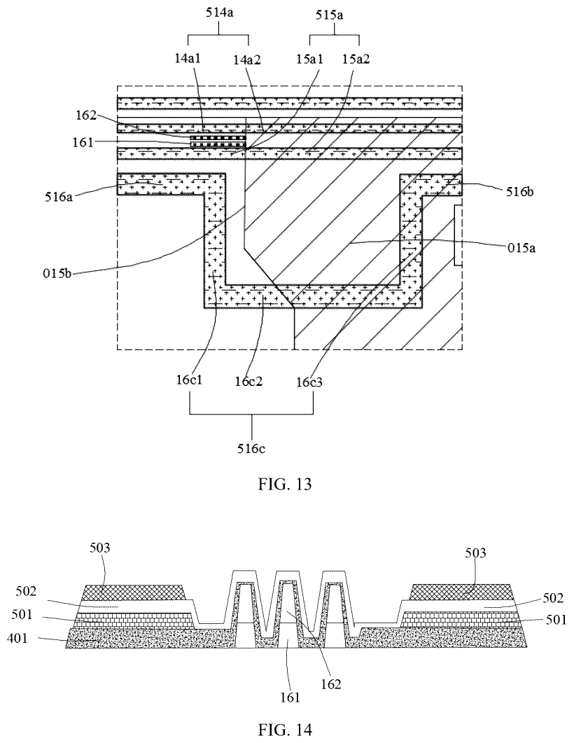

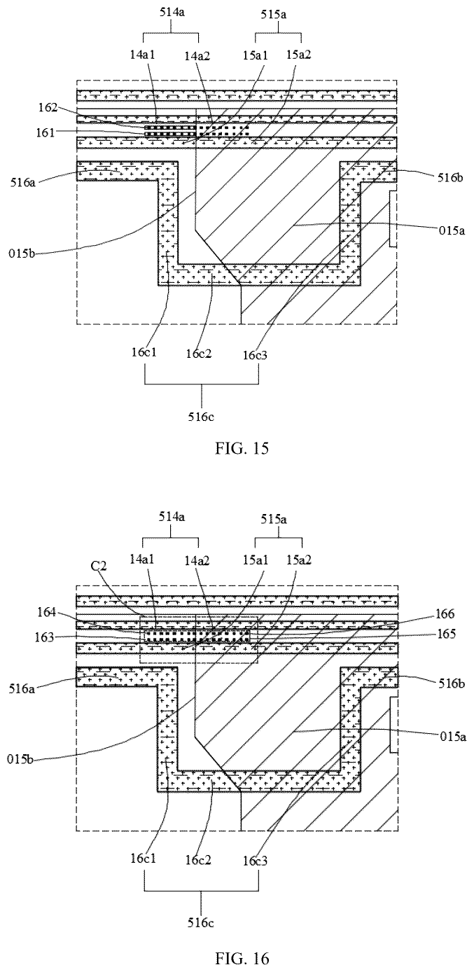

As shown in FIGS. 13 to 15, FIG. 14 is a cross-sectional view of the bump unit 016 in FIG. 15 along the third direction Y. In other embodiments of the present disclosure, the bump unit 016 further includes at least one second bump 162. The second bump 162 is disposed on a side of the first bump 161 or the second region 015 of the first organic layer 301 away from the base substrate 100. The orthographic projection of at least a portion of the second bumps 162 on the base substrate 100 is located within the orthographic projection of the first bump 161 on the base substrate 100. In this embodiment, all of the plurality of second bumps 162 may be disposed on a side of the first bump 161 away from the base substrate 100, and the orthographic projections of these second bumps 162 on the base substrate 100 are located within the orthographic projections of the first bumps 161 on the substrate 100. In a direction perpendicular to the base substrate 100, one or more second bumps 162 may be provided for one first bump 161. Further, as shown in FIG. 15, among the plurality of second bumps 162, some second bumps 162 may be disposed on a side of the first bump 161 away from the base substrate 100, with the orthographic projections of these second bumps 162 on the base substrate 100 located within the orthographic projection of the first bump 161 on the base substrate 100, and the remaining second bumps 162 may be disposed on a side of the second region 015 of the first organic layer 301 away from the base substrate 100, with the orthographic projections of these second bumps 162 on the base substrate 100 located within the orthographic projection of the second region 015 of the first organic layer 301 on the base substrate 100.

The orthographic projection of the second bump 162 on the base substrate 100 may be circular, elliptical, polygonal, or the like, and the cross-section of the second bump 162 in a direction perpendicular to the base substrate 100 may be rectangular, regular trapezoidal, inverted trapezoidal, or other polygonal shapes. Further, as shown in FIG. 14, the sum of heights of the first bump 161 and the second bump 162 in a direction perpendicular to the base substrate 100 is between 1.5 μm and 2.5 μm. Within this range, it not only prolongs the path for a short circuit that might occur during etching of the first touch trace 514 and the second touch trace 515, reduces the risk of a short circuit at the corresponding location, but also does not affect the preparation of other film layers, ensuring normal preparation of other film layers.

As shown in FIGS. 16 to 18, FIG. 17 is an enlarged view of section C in FIG. 16, and FIG. 18 is a cross-sectional view of the bump unit 016 in FIG. 16 along the third direction Y. In some further embodiments of the present disclosure, the bump unit 016 includes a first bump unit 163, the first bump unit 163 includes a plurality of third bumps 164. The plurality of third bumps 164 are arranged in an array between the first segment 514a of the first touch trace 514 and the first segment 515a of the second touch trace 515. The orthographic projections of the plurality of third bumps 164 on the base substrate 100 do not overlap with the second region 015 of the first organic layer 301, and the orthographic projections of the plurality of third bumps 164 on the base substrate 100 are located between the first sub-segment 14a1 of the first touch trace 514 and the first sub-segment 15a1 of the second touch trace 515.

The orthographic projection of the third bump 164 on the base substrate 100 can be circular, elliptical, or polygonal, and the cross-section of the third bump 164 in a direction perpendicular to the base substrate 100 can be rectangular, regular trapezoidal, inverted trapezoidal, or other polygonal shapes. Further, as shown in FIG. 18, the height of the third bump 164 in a direction perpendicular to the base substrate 100 is 1.5 μm-2.5 μm. Similar to the above embodiment, within this range, it not only prolongs the path for a short circuit that might occur during etching of the first touch trace 514 and the second touch trace 515, reduces the risk of a short circuit at the corresponding location, but also does not affect the preparation of other film layers, ensuring normal preparation of other film layers.

The bump unit 016 also includes a second bump unit 165, the second bump unit 165 is located on a side of the first bump unit 163 in the first direction X. The second bump unit 165 includes a plurality of fourth bumps 166, the plurality of fourth bumps 166 are arranged in an array between the first segment 514a of the first touch trace 514 and the first segment 515a of the second touch trace 515. The orthographic projections of the plurality of fourth bumps 166 on the base substrate 100 are located within the orthographic projection of the second region 015 of the first organic layer 301 on the base substrate 100.

The orthographic projection of the fourth bump 166 on the base substrate 100 can be circular, elliptical, or polygonal, the cross-section of the fourth bump 166 in a direction perpendicular to the base substrate 100 can be rectangular, regular trapezoidal, inverted trapezoidal, or other polygonal shapes. Further, the sum of heights of the fourth bump 166 and the second region 015 of the first organic layer 301 in a direction perpendicular to the base substrate 100 is 1.5 μm to 2.5 μm.

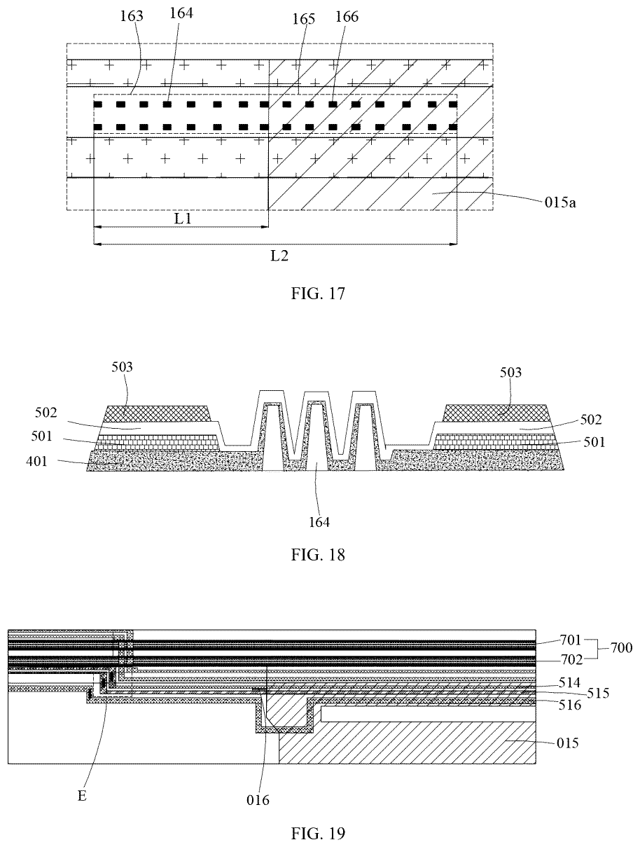

As shown in FIG. 17, the dimension L1 of the first bump unit 163 in the first direction X is not less than 35 μm, and the dimension L2 of the bump unit 016 in the first direction X is not larger than 200 μm. This numerical setting not only prolongs the path for a short circuit that might occur during etching of the first touch trace 514 and the second touch trace 515, reduces the risk of a short circuit at the corresponding location, but also does not affect the preparation of other film layers, ensuring normal preparation of other film layers. Further, the distance between the third bump 164 in the first bump unit 163 closest to the second region 015 of the first organic layer 301 and the second region 015 of the first organic layer 301 is not greater than 5 μm, and the distance between the outer edge of the third bump 164 in the first bump unit 163 farthest from the second region 015 of the first organic layer 301 and the second region 015 of the first organic layer 301 is not less than 35 μm. The outer edge of the third bump 164 refers to the edge of the third bump 164 away from the second region 015 of the first organic layer 301.

In the present disclosure, various structures included in the first organic layer 301, such as the pixel definition area 011, the first region 014, the second region 015, the isolation pillar 013 and the bump unit 016 can be formed through a single photolithography process. For example, a first organic material layer can be formed on the side of the first electrode layer 302 away from the base substrate 100, and then patterned using a semi-transparent film mask, to form the first organic layer 301.

In the present disclosure, the first touch trace 514 and the second touch trace 515 can be the double-layer or single-layer trace, and different trace segments of the first touch trace 514 and the second touch trace 515 can have different single-layer and double-layer configurations.

As shown in FIGS. 4, 8, 10, and 21, in some embodiments of the present disclosure, the first touch trace 514 is distributed in the first conductive layer 501 and the second conductive layer 503. The orthographic projections of traces of the first touch trace 514 distributed in different conductive layers on the base substrate 100 at least partially overlap, and the traces distributed in different conductive layers are connected through at least one first via hole 514c in the insulating layer 502. The second touch trace 515 is distributed in the first conductive layer 501 and the second conductive layer 503. The orthographic projections of traces of the second touch trace 515 distributed in different conductive layers on the base substrate 100 at least partially overlap, and the traces distributed in different conductive layers are connected through at least one second via hole 515c in the insulating layer 502. That is, the first touch trace 514 and the second touch trace 515 are double-layer traces. FIG. 21 shows a schematic diagram of via connections between traces distributed in different conductive layers.

Further, both the first touch trace 514 and the second touch trace 515 further include a second segment 514b or 515b extending along a third direction Y and connected to the first segment 514a or 515a. The third direction Y is not parallel with the first direction X. The orthographic projection of at least one first via hole 514c on the base substrate 100 is located within the orthographic projection of the second segment 514b of the first touch trace 514 on the base substrate 100. The orthographic projection of at least one second via hole 515c on the base substrate 100 is located within the orthographic projection of the second segment 515b of the second touch trace 515 on the base substrate 100. The line width of the second segment 514b of the first touch trace 514 is greater than the line width of the first segment 514a of the first touch trace 514. The line width of the second segment 515b of the second touch trace 515 is greater than the line width of the first segment 515a of the second touch trace 515. In this embodiment, the angle between the third direction Y and the first direction X can be 45°-90°. For example, in one embodiment, the angle between the third direction Y and the first direction X is 45°. In another embodiment, the third direction Y is substantially perpendicular to the first direction X.

As shown in FIGS. 19, 20, and 21, FIG. 20 is an enlarged view of portion E in FIG. 19, in some other embodiments of the present disclosure, the first segment 514a of the first touch trace 514 is distributed in the first conductive layer 501 or the second conductive layer 503; the first segment 515a of the second touch trace 515 is distributed in the first conductive layer 501 or the second conductive layer 503; and the first segment 514a of the first touch trace 514 and the first segment 515a of the second touch trace 515 are disposed in different layers. For example, the first segment 514a of the first touch trace 514 is located in the first conductive layer 501, while the first segment 515a of the second touch trace 515 is located in the second conductive layer 503. In another example, the first segment 514a of the first touch trace 514 is located in the second conductive layer 503, while the first segment 515a of the second touch trace 515 is located in the first conductive layer 501. In this embodiment, since the first segment 514a of the first touch trace 514 and the first segment 515a of the second touch trace 515 are located in different conductive layers, the distance between them two in a direction parallel to the base substrate 100 can be shortened, facilitating the narrow-frame design for the display panel.

In this embodiment, both the first touch trace 514 and the second touch trace 515 may also include a second segment 514b or 515b extending along a third direction Y and connected to the first segment 514a or 515a, where the third direction Y is not parallel with the first direction X. The second segment 514b of the first touch trace 514 and the second segment 515b of the second touch trace 515 can be double-layer traces, that is, the second segment 514b of the first touch trace 514 is distributed in the first conductive layer 501 and the second conductive layer 503. The orthographic projections of the traces of the first touch trace 514 distributed in different conductive layers on the base substrate 100 at least partially overlap, and the traces distributed in different conductive layers are connected through at least one first via hole 514c in the insulating layer 502. The second segment 515b of the second touch trace 515 is distributed in the first conductive layer 501 and the second conductive layer 503, the orthographic projections of the traces of the second touch trace 515 distributed in different conductive layers on the base substrate 100 at least partially overlap, and the traces distributed in different conductive layers are connected through at least one second via hole 515c in the insulating layer 502. The orthographic projection of at least one first via hole 514c on the base substrate 100 is located within the orthographic projection of the second segment 514b of the first touch trace 514 on the base substrate 100. The orthographic projection of at least one second via hole 515c on the base substrate 100 is located within the orthographic projection of the second segment 515b of the second touch trace 515 on the base substrate 100. The line width of the second segment 514b of the first touch trace 514 is greater than the line width of the first segment 514a of the first touch trace 514. The line width of the second segment 515b of the second touch trace 515 is greater than the line width of the first segment 515a of the second touch trace 515. Thus, the single-layer trace design of the first segments 514a or 515a of the first touch trace 514 and the second touch trace 515 facilitates achieving a narrower bezel design for the display panel, while the double-layer trace design of the second segments 514b or 515b of the first touch trace 514 and the second touch trace 515 facilitates reducing resistance and improving the stability and uniformity of the transmitted signal.

As shown in FIG. 7, in some embodiments of the present disclosure, the ground line 516 included in the touch layer 500 can be a single-layer trace or a double-layer trace, which is not specifically limited. The ground line 516 includes a first main segment 516a and a second main segment 516b extending along the first direction X and a bending segment 516c connecting the first main segment 516a and the second main segment 516b. The orthographic projection of the first main segment 516a on the base substrate 100 does not overlap with the orthographic projection of the second region 015 of the first organic layer 301 on the base substrate 100, and the orthographic projection of the second main segment 516b on the base substrate 100 is located within the orthographic projection of the second region 015 of the first organic layer 301 on the base substrate 100. The maximum distance between the bending segment 516c of the ground line 516 and the first segment 515a of the second touch trace is greater than the maximum distance between the first main segment 516a/second main segment 516b of the ground line 516 and the first segment 515a of the second touch trace. That is, the maximum distance between the bending segment 516c of the ground line 516 and the first segment 515a of the second touch trace is greater than the distance between the first main segment 516a and the first segment 515a of the second touch trace, and greater than the distance between the second main segment 516b and the first segment 515a of the second touch trace. This increases the distance between the ground line 516 and the second touch trace 515 at this location, which facilitates reducing the risk of a short circuit between the ground line 516 and the second touch trace 515.

The orthographic projection of the bending segment 516c on the base substrate 100 partially does not overlap with the orthographic projection of the second region 015 of the first organic layer 301 on the base substrate 100, and partially located within the orthographic projection of the second region 015 of the first organic layer 301 on the base substrate 100. The orthographic projection of the bending segment 516c on the base substrate 100 intersects with the orthographic projection of the edge of the second region 015 of the first organic layer 301 on the base substrate 100, forming a first angle α, where 0°<α<90°. That is, the edge of the second region 015 of the first organic layer 301 does not intersect the bending segment 516c perpendicularly. In this way, it may prolong the path for the etched metal remains, further reducing the risk of a short circuit between the second touch trace 515 and the ground line 516.

In one embodiment, the bending segment 516c includes a first bending sub-segment 16c1, a second bending sub-segment 16c2 and a third bending sub-segment 16c3 connected in sequence, the second bending sub-segment 16c1 extends along the first direction X, the first bending sub-segment 16c1 connects the first main segment 516a and the second bending sub-segment 16c2, and the third bending sub-segment 16c3 connects the second main segment 516b and the second bending sub-segment 16c2; the orthographic projection of the first bending sub-segment 16c1 on the base substrate 100 does not overlap with the orthographic projection of the second region 015 of the first organic layer 301 on the base substrate 100, and the orthographic projection of the third bending sub-segment 16c3 on the base substrate 100 is located within the orthographic projection of the second region 015 of the first organic layer 301 on the base substrate 100. Further, the orthographic projection of the second bending sub-segment 16c2 on the base substrate 100 intersects with the orthographic projection of the edge of the second region 015 of the first organic layer 301 on the base substrate 100 to form a first angle α.

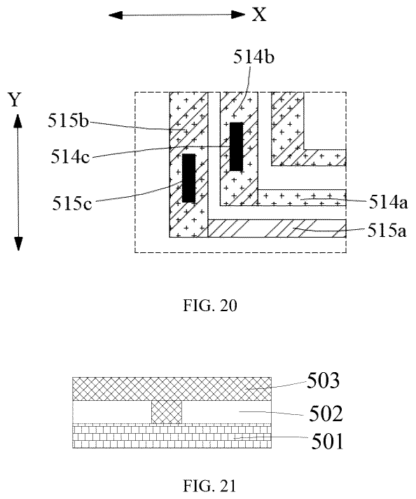

As shown in FIGS. 19 and 20, in some embodiments of the present disclosure, the first organic layer 301 may not include the bump unit 016. In such embodiments, the first segment 514a of the first touch trace 514 is distributed in the first conductive layer 501 or the second conductive layer 503, and the first segment 515a of the second touch trace 515 is distributed in the first conductive layer 501 or the second conductive layer 503, and the first segment 514a of the first touch trace 514 and the first segment 515a of the second touch trace 515 are disposed in different layers.

In this type of embodiments, the first touch trace 514 and the second touch trace 515 also include a second segment 514b or 515b extending along a third direction Y and connected to the first segment 514a or 515a, and the third direction Y is not parallel to the first direction X; the second segment 514b of the first touch trace 514 is distributed in both the first conductive layer 501 and the second conductive layer 503, and the orthographic projections of the traces distributed in different conductive layers in the first touch trace 514 on the base substrate 100 at least partially overlap, and the traces distributed in different conductive layers are connected through at least one first via hole 514c in the insulating layer 502; the second segment 515b of the second touch trace 515 is distributed in both the first conductive layer 501 and the second conductive layer 503, and the orthographic projections of the traces distributed in different conductive layers in the second touch trace 515 on the base substrate 100 at least partially overlap, and the traces distributed in different conductive layers are connected through at least one second via hole 515c in the insulating layer 502; the orthographic projection of at least one first via hole 514c on the base substrate 100 is located within the orthographic projection of the second segment 514b of the first touch trace 514 on the base substrate 100; the orthographic projection of at least one second via hole 515c on the base substrate 100 is located within the orthographic projection of the second segment 515b of the second touch trace 515 on the base substrate 100.

In addition, in this type of embodiments, the first organic layer 301 may also include a bump unit 016. The configuration of the bump unit 016 can refer to any of the above embodiments, which will not be described in detail here.

As shown in FIGS. 1 to 7, the present disclosure also provides a display panel including a base substrate 100, a first organic layer 301, a barrier dam 700, and a touch layer 500. The base substrate 100 includes a display area 110 and a peripheral area 120 located outside the display area 110. The peripheral area 120 includes a first peripheral area 121 and a second peripheral area 122 located on a side of the first peripheral area 121 away from the display area 110. The first organic layer 301 is disposed on a side of the base substrate 100 and includes a second region 015 located in the second peripheral area 122. The barrier dam 700 is disposed on a side of the base substrate 100 and is located in the first peripheral area 121. The touch layer 500 is disposed on the side of the first organic layer 301 away from the base substrate 100. The touch layer 500 includes a second touch trace 515. The second touch trace 515 includes a first segment 515a extending along the first direction X. The first segment 515a of the second touch trace 515 is located in the second peripheral area 122.

The touch layer 500 also includes a signal line 516, which is located on the side of the second touch trace 515 away from the display area 110. The signal line 516 includes a first main segment 516a and a second main segment 516b extending along the first direction X and a bending segment 516c connecting the first and second main segments 516a, 516b. The orthographic projection of the first main segment 516a on the base substrate 100 does not overlap with the orthographic projection of the second region 015 of the first organic layer 301 on the base substrate 100, and the orthographic projection of the second main segment 516b on the base substrate 100 is located within the orthographic projection of the second region 015 of the first organic layer 301 on the base substrate 100. The maximum distance between the bending segment 516c of the signal line 516 and the first segment 515a of the second touch trace is greater than the maximum distance between the first and second main segments 516a, 516b of the signal line 516 and the first segment 515a of the second touch trace. In one embodiment, the signal line 516 can be used to apply a ground signal, and can also be used to apply other signals.

In one embodiment, the bending segment 516c includes a first bending sub-segment 16c1, a second bending sub-segment 16c2 and a third bending sub-segment 16c3 which are connected in sequence. The second bending sub-segment 16c2 extends along the first direction. The first bending sub-segment 16c1 connects the first main segment 516a and the second bending sub-segment 16c2, and the third bending sub-segment 16c3 connects the second main segment 516b and the second bending sub-segment 16c2. The orthographic projection of the first bending sub-segment 16c1 on the base substrate 100 does not overlap with the orthographic projection of the second region 015 of the first organic layer 301 on the base substrate 100. The orthographic projection of the third bending sub-segment 16c3 on the base substrate 100 is located within the orthographic projection of the second region 015 of the first organic layer 301 on the base substrate 100.

The orthographic projection of the bending segment 516c on the base substrate 100 intersects with the orthographic projection of the edge of the second region 015 of the first organic layer 301 on the base substrate 100, forming a first angle α, where 0°<α<90°. Further, the orthographic projection of the second bending sub-segment 16c2 on the base substrate 100 intersects with the orthographic projection of the edge of the second region 015 of the first organic layer 301 on the base substrate 100, forming a first angle.

In this embodiment, the touch layer 500 further includes a first touch trace 514, and the first organic layer 301 further includes a bump unit 016. The configuration thereof can refer to in any of the above embodiments and will not be described in detail here.

This disclosure also provides a method for manufacturing a display panel, including following steps.

In step S100, a base substrate 100 is provided, the base substrate includes a display area 110 and a peripheral area 120 located outside the display area 110. The peripheral area 120 includes a first peripheral area 121 and a second peripheral area 122 located on a side of the first peripheral area 121 away from the display area 110.

In step S200, a first organic layer 301 and a barrier dam 700 are formed on a side of the base substrate 100. The first organic layer 301 includes a first region 014 and a second region 015. The first region 014 is located in the first peripheral area 121, and the second region 015 is located in the second peripheral area 122. The barrier dam 700 is located in the first peripheral area 121, the barrier dam 700 includes the first region 014 of the first organic layer 301.

In step S300, a touch layer 500 is formed on a side of the first organic layer 301 away from the base substrate 100. The touch layer 500 includes a first touch trace 514 and a second touch trace 515. Each of the first touch trace 514 and the second touch trace 515 includes a first segment 514a or 515a extending along the first direction X. The first segments 514a or 515a of the first touch trace 514 and the second touch trace 515 are located in the second peripheral area 122.

Each of the first segments 514a and 515a of the first touch trace 514 and the second touch trace 515 includes a first sub-segment 14a1 or 15a1 and a second sub-segment 14a2 or 15a2 connected to each other. The first sub-segment 14a1 or 15a1 and the second sub-segment 14a2 or 15a2 of the first touch trace 514 are at different distances from the base substrate 100. The first sub-segment 14a1 or 15a1 and the second sub-segment 14a2 or 15a2 of the second touch trace 515 are at different distances from the base substrate 100.

The orthographic projections of the first sub-segments 14a1 or 15a1 of the first touch trace 514 and the second touch trace 515 on the base substrate 100 do not overlap with the orthographic projection of the first organic layer 301 on the base substrate 100.

The orthographic projections of the second sub-segments 14a2 or 15a2 of the first touch trace 514 and the second touch trace 515 on the base substrate 100 are located within the orthographic projection of the second region 015 of the first organic layer 301 on the base substrate 100.

The first organic layer 301 further includes a bump unit 016, the orthographic projection of the bump unit 016 on the base substrate 100 is at least partially located between the orthographic projections of the first sub-segment 14a1 or 15a1 of the first touch trace 514 and the first sub-segment 14a1 or 15a1 of the second touch trace 515 on the base substrate 100.

The present disclosure also provides a display device including a display panel. The display panel can be any display panel of the above-mentioned embodiments. The specific structure and beneficial effects thereof can refer to the above-mentioned embodiments of the display panel, which will not be further described here. The display device of the present disclosure can be an electronic device such as a mobile phone, a tablet computer, or a television, which will not be listed here.

It should be noted that although the steps of the method of the present disclosure are depicted in a particular order in the drawings, this does not require or imply that the steps must be performed in this particular order, or that all steps must be performed to achieve the desired result. Additional or alternatively, omitting certain steps, combining multiple steps into a single step, and/or decomposing a single step into multiple steps are considered part of this disclosure.

It should be understood that, this disclosure is not limited in its application to the detailed construction and arrangement of components set forth in this specification. The disclosure can have other embodiments and can be implemented and carried out in a variety of ways. Such variations and modifications are within the scope of this disclosure. It should be understood that, the disclosure disclosed and defined in this specification extends to all alternative combinations of two or more of the individual features mentioned or evident from the text and/or drawings. All such different combinations constitute multiple alternative aspects of this disclosure. The embodiments described herein illustrate the best known manners for carrying out this disclosure and will enable those skilled in the art to utilize this disclosure.

1. A display panel, comprising:
a base substrate, comprising a display area and a peripheral area located outside the display area, wherein the peripheral area comprises a first peripheral area and a second peripheral area located at a side of the first peripheral area away from the display area;
a first organic layer, disposed on a side of the base substrate, wherein the first organic layer comprises a second region, the second region is located in the second peripheral area;
a barrier dam, disposed on a side of the base substrate, wherein the barrier dam is located in the first peripheral area;
a touch layer, disposed on a side of the first organic layer away from the base substrate, wherein the touch layer comprises a first touch trace and a second touch trace, each of the first touch trace and the second touch trace comprises a first segment extending in a first direction, each of the first segments of the first touch trace and the second touch trace is located in the second peripheral area;
wherein each of the first segments of the first touch trace and the second touch trace comprises a first sub-segment and a second sub-segment connected to each other, the first sub-segment and the second sub-segment of the first touch trace are at different distances from the base substrate, and the first sub-segment and the second sub-segment of the second touch trace are at different distances from the base substrate;
orthographic projections of the first sub-segments of the first touch trace and the second touch trace on the base substrate do not overlap with an orthographic projection of the first organic layer on the base substrate;
orthographic projections of the second sub-segments of the first touch trace and the second touch trace on the base substrate are located within an orthographic projection of the second region of the first organic layer on the base substrate;
the first organic layer further comprises a bump unit, an orthographic projection of the bump unit on the base substrate is at least partially located between the orthographic projections of the first sub-segment of the first touch trace and the first sub-segment of the second touch trace on the base substrate.

2. The display panel according to claim 1, further comprising:
an encapsulation layer, disposed between the first organic layer and the touch layer, wherein the encapsulation layer comprises a first inorganic layer, a second organic layer and a second inorganic layer stacked in a direction away from the base substrate, an orthographic projection of the second organic layer on the base substrate is located on a side of an orthographic projection of the barrier dam on the base substrate away from the second peripheral area.

3. The display panel according to claim 1, wherein a distance between the first segment of the first touch trace and the first segment of the second touch trace in a direction parallel to the base substrate is not greater than 20 μm.

4. The display panel according to claim 1, wherein the bump unit comprises a first bump;
the second region of the first organic layer has a first edge extending in a second direction, the second direction is not parallel with the first direction;
at least a portion of the first edge of the second region of the first organic layer protrudes along the first direction toward the first sub-segment to form at least one of the first bumps.

5. The display panel according to claim 4, wherein a dimension of the first bump in the first direction is not less than 35 μm;
in a direction parallel to the base substrate, the shortest distance between an edge of the first bump and the first touch trace or the second touch trace is not less than 4 μm.

6. The display panel according to claim 4, wherein the bump unit further comprises at least one second bump, the second bump is disposed on a side of the first bump or the second region of the first organic layer away from the base substrate, an orthographic projection of at least a portion of the second bump on the base substrate is located within an orthographic projection of the first bump on the base substrate,
wherein, in a direction perpendicular to the base substrate, a sum of heights of the first bump and the second bump is 1.5 μm-2.5 μm.

7-11. (canceled)

12. The display panel according to claim 1, wherein the first segment of the second touch trace is located on a side of the first segment of the first touch trace away from the display area;
the touch layer further comprises a ground line, the ground line comprises a first main segment and a second main segment extending along the first direction and a bending segment connecting between the first main segment and the second main segment, an orthographic projection of the first main segment on the base substrate does not overlap with the orthographic projection of the second region of the first organic layer on the base substrate, and an orthographic projection of the second main segment on the base substrate is located within the orthographic projection of the second region of the first organic layer on the base substrate;
a maximum distance between the bending segment of the ground line and the first segment of the second touch trace is greater than a maximum distance between the first and second main segments of the ground line and the first segment of the second touch trace.

13. The display panel according to claim 12, wherein an orthographic projection of the bending segment on the base substrate intersects with an orthographic projection of an edge of the second region of the first organic layer on the base substrate to form a first angle α, where 0°<α<90°.

14. The display panel according to claim 13, wherein the bending segment comprises a first bending sub-segment, a second bending sub-segment and a third bending sub-segment connected in sequence, the second bending sub-segment extends along the first direction, the first bending sub-segment connects the first main segment and the second bending sub-segment, and the third bending sub-segment connects the second main segment and the second bending sub-segment;
an orthographic projection of the first bending sub-segment on the base substrate does not overlap with the orthographic projection of the second region of the first organic layer on the base substrate, and an orthographic projection of the third bending sub-segment on the base substrate is located within the orthographic projection of the second region of the first organic layer on the base substrate;
an orthographic projection of the second bending sub-segment on the base substrate intersects with the orthographic projection of the edge of the second region of the first organic layer on the base substrate to form the first angle.

15. The display panel according to claim 12, wherein the touch layer further comprises a plurality of driving electrodes and a plurality of receiving electrodes, the driving electrodes are configured to receive touch driving signals, the first touch trace is connected with the receiving electrodes for transmitting a mutual capacitance change signal between the driving electrodes and the receiving electrodes;
the second touch trace is configured to apply a shielding signal.

16. The display panel according to claim 1, wherein the touch layer further comprises a first conductive layer, an insulating layer and a second conductive layer stacked in a direction away from the base substrate;
the first segment of the first touch trace is located in the first conductive layer or the second conductive layer;
the first segment of the second touch trace is located in the first conductive layer or the second conductive layer;
and the first segment of the first touch trace and the first segment of the second touch trace are located in different layers,
wherein each of the first touch trace and the second touch trace further comprises a second segment extending along a third direction and connected with the first segment, the third direction is not parallel with the first direction;
the second segment of the first touch trace is distributed in both the first conductive layer and the second conductive layer, orthographic projections of traces of the first touch trace distributed in different conductive layers on the base substrate at least partially overlap, and traces of the first touch trace distributed in different conductive layers are connected through at least one first via hole in the insulating layer;
the second segment of the second touch trace is distributed in both the first conductive layer and the second conductive layer, orthographic projections of traces of the second touch trace distributed in different conductive layers on the base substrate at least partially overlap, and traces of the second touch trace distributed in different conductive layers are connected through at least one second via hole in the insulating layer;
an orthographic projection of the at least one first via hole on the base substrate is located within the orthographic projection of the second segment of the first touch trace on the base substrate;
an orthographic projection of the at least one second via hole on the base substrate is located within the orthographic projection of the second segment of the second touch trace on the base substrate.

17. (canceled)

18. The display panel according to claim 1, wherein the touch layer comprises a first conductive layer, an insulating layer and a second conductive layer stacked in a direction away from the base substrate;
the first touch trace is distributed in both the first conductive layer and the second conductive layer, orthographic projections of traces of the first touch trace distributed in different conductive layers on the base substrate at least partially overlap, and traces of the first touch trace distributed in different conductive layers are connected through at least one first via hole in the insulating layer;
the second touch trace is distributed in both the first conductive layer and the second conductive layer, orthographic projections of traces of the second touch trace distributed in different conductive layers on the base substrate at least partially overlap, and traces of the second touch trace distributed in different conductive layers are connected through at least one second via hole in the insulating layer.

19. The display panel according to claim 18, wherein each of the first touch trace and the second touch trace further comprises a second segment extending along a third direction and connected with the first segment, the third direction is not parallel with the first direction;
an orthographic projection of the at least one first via hole on the base substrate is located within the orthographic projection of the second segment of the first touch trace on the base substrate;
an orthographic projection of the at least one second via hole on the base substrate is located within the orthographic projection of the second segment of the second touch trace on the base substrate.

20. The display panel according to claim 17, of wherein a line width of the second segment of the first touch trace is greater than a line width of the first segment of the first touch trace;
a line width of the second segment of the second touch trace is greater than a line width of the first segment of the second touch trace.

21. The display panel according to claim 1, further comprising a driving chip;
wherein the second peripheral area comprises a bonding area, the second region of the first organic layer is at least partially located in the bonding area, and a surface of the second region of the first organic layer away from the base substrate is provided with a groove, the driving chip is located within the groove.

22-23. (canceled)

24. A display panel, comprising:
a base substrate, comprising a display area and a peripheral area located outside the display area, wherein the peripheral area comprises a first peripheral area and a second peripheral area located at a side of the first peripheral area away from the display area;
a first organic layer, disposed on a side of the base substrate, wherein the first organic layer comprises a second region, the second region is located in the second peripheral area;
a barrier dam, disposed on a side of the base substrate, wherein the barrier dam is located in the first peripheral area;
a touch layer, disposed on a side of the first organic layer away from the base substrate, wherein the touch layer comprises a second touch trace, the second touch trace comprises a first segment extending in a first direction, the first segment of the second touch trace is located in the second peripheral area;
the touch layer further comprises a signal line, wherein the signal line is located on a side of the second touch trace away from the display area;
the signal line comprises a first main segment and a second main segment extending along the first direction and a bending segment connecting between the first main segment and the second main segment, an orthographic projection of the first main segment on the base substrate does not overlap with the orthographic projection of the second region of the first organic layer on the base substrate, and an orthographic projection of the second main segment on the base substrate is located within the orthographic projection of the second region of the first organic layer on the base substrate;
a maximum distance between the bending segment of the signal line and the first segment of the second touch trace is greater than a maximum distance between the first and second main segments of the signal line and the first segment of the second touch trace,
wherein the signal line is used to apply a ground signal.

25. (canceled)

26. The display panel according to claim 24, wherein the bending segment comprises a first bending sub-segment, a second bending sub-segment and a third bending sub-segment connected in sequence, the second bending sub-segment extends along the first direction, the first bending sub-segment connects the first main segment and the second bending sub-segment, and the third bending sub-segment connects the second main segment and the second bending sub-segment;
an orthographic projection of the first bending sub-segment on the base substrate does not overlap with the orthographic projection of the second region of the first organic layer on the base substrate, and an orthographic projection of the third bending sub-segment on the base substrate is located within the orthographic projection of the second region of the first organic layer on the base substrate.

27. The display panel according to claim 24, wherein an orthographic projection of the bending segment on the base substrate intersects with an orthographic projection of an edge of the second region of the first organic layer on the base substrate to form a first angle α, where 0°<α<90°;
wherein the bending segment comprises a first bending sub-segment, a second bending sub-segment and a third bending sub-segment connected in sequence, the second bending sub-segment extends along the first direction, the first bending sub-segment connects the first main segment and the second bending sub-segment, and the third bending sub-segment connects the second main segment and the second bending sub-segment;
an orthographic projection of the first bending sub-segment on the base substrate does not overlap with the orthographic projection of the second region of the first organic layer on the base substrate, and an orthographic projection of the third bending sub-segment on the base substrate is located within the orthographic projection of the second region of the first organic layer on the base substrate;
an orthographic projection of the second bending sub-segment on the base substrate intersects with the orthographic projection of the edge of the second region of the first organic layer on the base substrate to form the first angle.

28. (canceled)

29. The display panel according to claim 1, wherein the first organic layer further comprises a first region, the first region is located in the first peripheral area, and the barrier dam comprises the first region of the first organic layer.

30. A display device, comprising a display panel, wherein the display panel comprises:
a base substrate, comprising a display area and a peripheral area located outside the display area, wherein the peripheral area comprises a first peripheral area and a second peripheral area located at a side of the first peripheral area away from the display area;
a first organic layer, disposed on a side of the base substrate, wherein the first organic layer comprises a second region, the second region is located in the second peripheral area;
a barrier dam, disposed on a side of the base substrate, wherein the barrier dam is located in the first peripheral area;
a touch layer, disposed on a side of the first organic layer away from the base substrate, wherein the touch layer comprises a first touch trace and a second touch trace, each of the first touch trace and the second touch trace comprises a first segment extending in a first direction, each of the first segments of the first touch trace and the second touch trace is located in the second peripheral area;
wherein each of the first segments of the first touch trace and the second touch trace comprises a first sub-segment and a second sub-segment connected to each other, the first sub-segment and the second sub-segment of the first touch trace are at different distances from the base substrate, and the first sub-segment and the second sub-segment of the second touch trace are at different distances from the base substrate;
orthographic projections of the first sub-segments of the first touch trace and the second touch trace on the base substrate do not overlap with an orthographic projection of the first organic layer on the base substrate;
orthographic projections of the second sub-segments of the first touch trace and the second touch trace on the base substrate are located within an orthographic projection of the second region of the first organic layer on the base substrate;
the first organic layer further comprises a bump unit, an orthographic projection of the bump unit on the base substrate is at least partially located between the orthographic projections of the first sub-segment of the first touch trace and the first sub-segment of the second touch trace on the base substrate.
